(19) United States
(12) Patent Application Publication
(10) Pub. No.: US 2026/0163766 A1
(43) Pub. Date: Jun. 11, 2026

(54) CHANNEL PREDICTION METHOD, APPARATUS, AND PROGRAM BASED ON WIRELESS ENVIRONMENTAL INFORMATION

(71) Applicant: Beijing University of Posts and Telecommunications, Beijing (CN)

(72) Inventors: Jianhua Zhang, Beijing (CN); Yichen Cai, Beijing (CN); Li Yu, Beijing (CN); Yuxiang Zhang, Beijing (CN); Lianzheng Shi, Beijing (CN)

(21) Appl. No.: 19/181,579

(22) Filed: Apr. 17, 2025

(30) Foreign Application Priority Data
Aug. 12, 2024 (CN) 2024110972501

(51) Int. Cl. H04L 25/02; G06F 30/10; G06N 3/0985

(52) U.S. Cl. CPC H04L 25/0254; G06F 30/10; G06N 3/0985

(57) ABSTRACT

An environmental intelligence communication architecture includes: reconstructing a three-dimensional scene model according to environmental multi-modal sensing data; extracting wireless environmental information; predicting channel fading states according to the wireless environmental information and a target channel prediction model; and generating an optimal transmission strategy according to an actual situation. A channel prediction method includes: obtaining, according to a target pilot pattern, partial CSI under a first wireless scene as first CSI, and obtaining multi-view image data of the first wireless scene; and predicting complete CSI under the first wireless scene according to the first CSI, the multi-view image data of the first wireless scene and a target channel prediction model. The target channel prediction model includes: an image feature extraction neural network configured to extract image features from the multi-view image data, the target pilot pattern and a CSI reconstruction neural network configured to predict the complete CSI.

### CROSS-REFERENCE TO RELATED APPLICATION

This application claims priority to Chinese Patent Application No. 202411097250.1, filed Aug. 12, 2024, which is herein incorporated by reference in its entirety.

### TECHNICAL FIELD

The disclosure relates to the field of wireless technologies, and more particularly to a channel prediction method, an apparatus, and a program based on wireless environmental information.

### BACKGROUND

In a large-scale multiple input multiple output (MIMO) system for sixth-generation (6G), the scale of antenna arrays is continuously expanding, and the number of antennas is increasing. As an important component of a wireless communication system, the application of large-scale MIMO technology brings many benefits to the wireless communication system, including high spectral efficiency, high energy efficiency, high spatial resolution, and high beamforming gain. To realize these advantages, the large-scale MIMO system for 6G needs to obtain accurate channel fading states.

Essentially, electromagnetic waves transmitted from a transmitter encounter buildings, vegetation and other scatterers, to thereby produce multipath effects. The superposition of the electromagnetic waves propagating along different paths leads to channel fading. Therefore, the channel fading state ultimately depends on how the electromagnetic waves interact with objects in an environment. With the pursuit of higher capacity and data rates in the 6G, especially in facing highly variable environments, there is an urgent need for a new paradigm which is more proactive and online to combat the randomness of the channel fading.

Currently, a channel prediction method based on artificial intelligence (AI) can actively acquire channel state information (CSI) in the large-scale MIMO system with lower pilot overhead. Given that channels exhibit certain correlations in spatial, temporal, and frequency dimensions, the channel prediction method based on AI can explore deep relationships of multi-domain channels across space, time, and frequency, thereby reducing necessary multidimensional pilot signals.

However, traditional AI-based channel prediction algorithms currently use partial CSI from some antennas, moments, and frequencies to predict whole CSI without considering wireless environmental information. These data-driven algorithms generate prediction models based solely on training data and struggle to generalize to other scenes. Therefore, the traditional AI-based channel prediction algorithms are only suitable for relatively stable static environments and cannot achieve stable prediction performance with low overhead in dynamic scenes. In the complex and variable 6G channels of the future, the above algorithms are no longer sufficient to meet the requirements.

### SUMMARY

The disclosure is to provide an environmental intelligence communication architecture, and a channel prediction method, apparatus, and program based on wireless environmental information, to solve the problem that existing channel prediction algorithms cannot achieve high-precision and low-overhead channel prediction in dynamic environmental scenes.

In order to solve above technical problems, an embodiment of the disclosure provides the following technical solutions.

In a first aspect, the embodiment of the disclosure provides an environmental intelligence communication architecture, including:
reconstructing a high-precision three-dimensional model of scenes according to environmental multi-modal sensing data obtained by sensing devices including: a camera and a radar, where the scenes include: a first wireless scene and a second wireless scene;
performing wireless knowledge mapping on the high-precision three-dimensional model of the scenes according to communication task requirements of a physical layer, a resource layer, a network function layer and an application layer, to extract wireless environmental information related to tasks;
predicting possible channel fading states (also referred to as CSI) according to the wireless environmental information and an artificial intelligence (AI) prediction algorithm, where the AI prediction algorithm includes: a first neural network and a second neural network; generating proactively communication decisions for respective situations according to the possible channel fading states; and
selecting an optimal transmission strategy according to an actual situation.

In an embodiment, the communication decision includes: selection of coding and modulation schemes, power control, and beamforming at the physical layer; allocation of time and frequency spectrum resources at the resource layer; network planning, network optimization, and cell switching at the network layer; and quality of service (QoS) optimization and enhancement at the application layer.

In an embodiment, the step of predicting possible channel fading states according to the wireless environmental information and an AI prediction algorithm is embodied by the following channel prediction method.

In a second aspect, the embodiment of the disclosure provides a channel prediction method, including:
acquiring, according to a target pilot pattern, partial channel state information (CSI) under a first wireless scene as first CSI, and acquiring multi-view image data of the first wireless scene; and
predicting complete CSI under the first wireless scene according to the first CSI, the multi-view image data of the first wireless scene and a target channel prediction model.

The target channel prediction model includes: an image feature extraction neural network, the target pilot pattern and a CSI reconstruction neural network. The image feature extraction neural network is configured to extract image features from the multi-view image data of the first wireless scene. The CSI reconstruction neural network is configured to predict the complete CSI according to the image features and the first CSI. The image feature extraction neural network, the target pilot pattern and the CSI reconstruction neural network are obtained by training according to second CSI being complete CSI in a simulation environment of the first wireless scene, and multi-view image data in the simulation environment of the first wireless scene.

In an embodiment, the channel prediction method further includes:
obtaining the second CSI from receivers at target positions in the simulation environment of the first wireless scene, and obtaining the multi-view image data from the receivers at the target positions in the simulation environment of the first wireless scene, where the target positions include a first position and a second position;
training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters;
predicting third CSI at the second position according to the second CSI at the second position, the second pilot pattern, the second image feature extraction parameters, the first network hyperparameters of the first neural network, the multi-view image data at the second position and the second CSI reconstruction parameters;
obtaining first error information and first similarity information between the second CSI at the second position and the third CSI at the second position;
in response to the first error information and the first similarity information not meeting a first preset condition, adjusting the first network hyperparameters of the first neural network; and
returning to the step of training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters, until the first error information and the first similarity information meet the first preset condition; obtaining the image feature extraction neural network according to adjusted first network hyperparameters obtained by a final adjustment and the second image feature extraction parameters corresponding to the adjusted first network hyperparameters obtained by the final adjustment; taking the second pilot pattern corresponding to the adjusted first network hyperparameters obtained by the final adjustment as the target pilot pattern; and obtaining the CSI reconstruction neural network according to the first CSI reconstruction parameters of the second neural network corresponding to the adjusted first network hyperparameters obtained by the final adjustment.

In an embodiment, the training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters includes:
performing, according to the first image feature extraction parameters of the first neural network, feature extraction on the multi-view image data at the first position by using the first neural network to obtain an environmental feature map;
obtaining, according to the first pilot pattern and the second CSI at the first position, partial CSI at the first position as fourth CSI;
obtaining, according to the first CSI reconstruction parameters of the second neural network, the environmental feature map and the fourth CSI, predicted complete CSI in the simulation environment of the first wireless scene as fifth CSI;
obtaining loss information between the fifth CSI and the second CSI in the simulation environment of the first wireless scene;
adjusting the first image feature extraction parameters of the first neural network according to the loss information, adjusting the first pilot pattern according to the loss information and a deep probabilistic subsampling algorithm, adjusting the first CSI reconstruction parameters of the second neural network according to the loss information, and returning to the step of performing, according to the first image feature extraction parameters of the first neural network, feature extraction on the multi-view image data at the first position by using the first neural network to obtain an environmental feature map, until a number of iterations reaches a preset number; and
taking adjusted first image feature extraction parameters obtained by a last adjustment as the second image feature extraction parameters, taking adjusted first pilot pattern obtained by the last adjustment as the second pilot pattern, and taking adjusted first CSI reconstruction parameters obtained by the last adjustment as the second CSI reconstruction parameters.

In an embodiment, the obtaining, according to the first CSI reconstruction parameters of the second neural network, the environmental feature map and the fourth CSI, predicted complete CSI in the simulation environment of the first wireless scene as fifth CSI includes:
predicting the fifth CSI by using the second neural network and a proximal gradient iteration algorithm according to the first CSI reconstruction parameters of the second neural network, the environmental feature map and the fourth CSI.

In an embodiment, the first preset condition includes: the first error information being less than second error information corresponding to a first channel prediction model, and the first similarity information being greater than second similarity information corresponding to the first channel prediction model.

The first channel prediction model includes at least one of the following:
a first sub-channel prediction model, including: a randomly generated second pilot pattern and the CSI reconstruction neural network;
a second sub-channel prediction model, including: a randomly generated second pilot pattern, the image feature extraction neural network, and the CSI reconstruction neural network; and
a third sub-channel prediction model, including: the target pilot pattern and the CSI reconstruction neural network.

In an embodiment, the channel prediction method further includes:
obtaining environmental information of the first wireless scene; and
constructing the simulation environment of the first wireless scene by using a modeling tool according to the environmental information of the first wireless scene.

In an embodiment, the obtaining the second CSI from receivers at target positions in the simulation environment of the first wireless scene includes:
generating, by using a ray-tracing channel simulation tool, the second CSI from the receivers at the target positions in the simulation environment of the first wireless scene.

In an embodiment, the obtaining the multi-view image data from the receivers at the target positions in the simulation environment of the first wireless scene includes:
obtaining, by using an autonomous driving simulation platform, the multi-view image data from the receivers at the target positions in the simulation environment of the first wireless scene.

In an embodiment, the target positions further include a third position; and the channel prediction method further includes:
obtaining partial CSI at the third position as sixth CSI according to the second SCI at the third position and the target pilot pattern;
extracting, by using the image feature extraction neural network, image features of the multi-view image data at the third position;
predicting, through the CSI reconstruction neural network, complete CSI at the third position as seventh CSI, according to the image features of the multi-view image data at the third position, and the sixth CSI; and
obtaining an accuracy of the target channel prediction model according to third error information and third similarity information between the seventh CSI and the second CSI at the third position.

In an embodiment, the channel prediction method further includes:
obtaining complete CSI in a simulation environment of a second wireless scene as eighth CSI, and obtaining multi-view image data from receivers in the simulation environment of the second wireless scene;
obtaining, according to the eighth CSI and the target pilot pattern, partial CSI in the simulation environment of the second wireless scene as ninth CSI;
extracting, by using the image feature extraction neural network, image features of the multi-view image data in the simulation environment of the second wireless scene;
obtaining, through the CSI reconstruction neural network, predicted complete CSI in the simulation environment of the second wireless scene as tenth CSI, according to the image features of the multi-view image data in the simulation environment of the second wireless scene and the ninth CSI; and
obtaining a generalization applicability result of the target channel prediction model according to fourth error information and fourth similarity information between the tenth CSI and the eighth CSI.

In a third aspect, the embodiment of the disclosure provides a channel prediction apparatus, including:
a first acquisition module, configured to acquire partial CSI under a first wireless scene as first CSI according to a target pilot pattern and acquire multi-view image data of the first wireless scene; and
a first processing module, configured to predict complete CSI under the first wireless scene according to the first CSI, the multi-view image data of the first wireless scene and a target channel prediction model;
where the target channel prediction model includes: an image feature extraction neural network, the target pilot pattern and a CSI reconstruction neural network; the image feature extraction neural network is configured to extract image features from the multi-view image data of the first wireless scene; the CSI reconstruction neural network is configured to predict the complete CSI according to the image features and the first CSI; and the image feature extraction neural network, the target pilot pattern and the CSI reconstruction neural network are obtained by training according to second CSI being complete CSI in a simulation environment of the first wireless scene, and multi-view image data in the simulation environment of the first wireless scene.

In an embodiment, each of the three-dimensional model of the scenes, the target channel prediction model, the first channel prediction model, the first sub-channel prediction model, the second sub-channel prediction model, the third sub-channel prediction model, the first acquisition module and the first processing module is embodied by at least one processor and at least one memory coupled to the at least one processor, and the at least one memory stores computer programs executable by the at least one processor.

In a fourth aspect, the embodiment of the disclosure further provides a channel prediction device, including: a transceiver, a processor, a memory and a program or instructions stored on the memory and executed on the processor; where the program or the instructions are configured to, when are executed by the processor, implement the steps of the channel prediction method.

In a fifth aspect, the embodiment of the disclosure further provides a non-transitory computer-readable storage medium, the non-transitory computer-readable storage medium is stored with a program or instructions, and the program or instructions are configured to, when are executed by a processor, implement the steps of the channel prediction method.

In a sixth aspect, the embodiment of the disclosure further provides a computer program product, including: computer instructions; where the computer instructions are configured to, when are executed by a processer, implement the steps of the channel prediction method.

The above technical solutions of the disclosure have the following beneficial effects.

The channel prediction method provided by the technical solutions of the disclosure obtains the partial CSI under the first wireless scene as the first CSI according to the target pilot pattern, extracts the image features of the multi-view image data of the first wireless scene by using the image feature extraction neural network of the target channel prediction model, and predicts the complete CSI under the first wireless scene, by using the CSI reconstruction neural network of the target channel prediction model, according to the image features of the multi-view image data of the first wireless scene and the first CSI, thereby achieving a high-precision and low-overhead CSI prediction to meet the demands of future communication systems under a premise of considering the dynamic environmental scenes.

### BRIEF DESCRIPTION OF DRAWINGS

FIG. 1 illustrates a flowchart of an environmental intelligence communication architecture according to an embodiment of the disclosure.

FIG. 2 illustrates a flowchart of a channel prediction method according to the embodiment of the disclosure.

FIG. 3 illustrates a schematic diagram of an error information comparison results according to the embodiment of the disclosure.

FIG. 4 illustrates a schematic diagram of a similarity comparison result according to the embodiment of the disclosure.

FIG. 5 illustrates a schematic diagram of predicting complete CSI according to the embodiment of the disclosure.

FIG. 6 illustrates a schematic structural diagram of neural networks of the target channel prediction model according to the embodiment of the disclosure.

FIG. 7 illustrates a schematic structural diagram of a channel prediction apparatus according to the embodiment of the disclosure.

FIG. 8 illustrates a schematic structural diagram of a channel prediction device according to the embodiment of the disclosure.

### DETAILED DESCRIPTION OF EMBODIMENTS

In order to clarify the technical problem to be solved, technical solutions, and advantages by the disclosure, a detailed description is provided below in conjunction with the accompanying drawings and specific embodiments.

In order to solve the problem that existing channel prediction algorithms cannot achieve high-precision and low-overhead channel prediction in dynamic environmental scenes, an embodiment of the disclosure provides an environmental intelligence communication architecture, and a channel prediction method, apparatus, and program based on wireless environmental information.

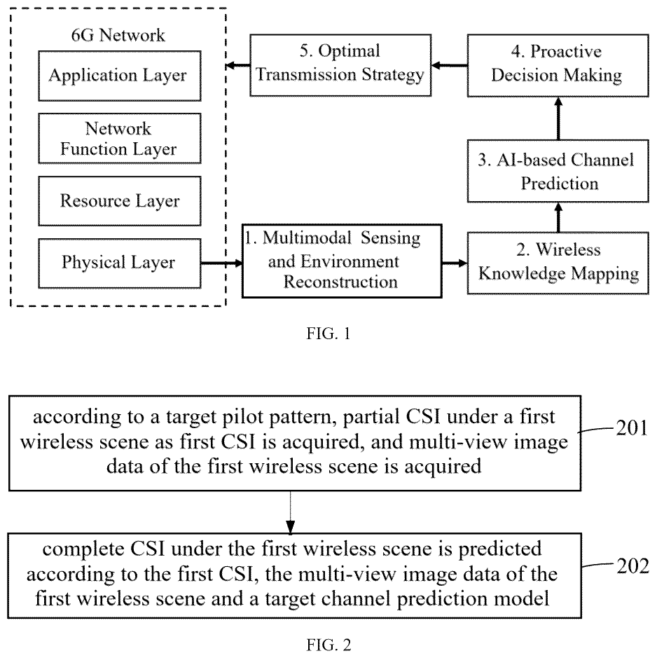

As shown in FIG. 1, the embodiment of the disclosure provides the environmental intelligence communication architecture, including the following steps:
step 101: reconstructing a high-precision three-dimensional model of scenes according to environmental multi-modal sensing data obtained by sensing devices including: a camera and a radar, where the scenes include: a first wireless scene and a second wireless scene;
step 102: performing wireless knowledge mapping on the high-precision three-dimensional model of the scenes according to communication task requirements of a physical layer, a resource layer, a network function layer and an application layer, to extract wireless environmental information related to tasks;
step 103: predicting possible channel fading states according to the wireless environmental information and an artificial intelligence (AI) prediction algorithm, where the AI prediction algorithm includes: a first neural network and a second neural network;
step 104: generating proactively communication decisions for respective situations according to the possible channel fading states; and
step 105: selecting an optimal transmission strategy according to an actual situation.

As shown in FIG. 2, the embodiment of the disclosure provides the channel prediction method, including the following steps 201-202.

Step 201: according to a target pilot pattern, partial CSI under a first wireless scene as first CSI is acquired, and multi-view image data of the first wireless scene is acquired.

The target pilot pattern is obtained by training according to second CSI being complete CSI in a simulation environment of the first wireless scene, and multi-view image data in the simulation environment of the first wireless scene.

It should be noted that, there is an optimal pilot pattern for each scene to facilitate the selection of pilot positions. Specifically, the target pilot pattern is trained according to the second CSI being the complete CSI in the simulation environment of the first wireless scene, and the multi-view image data in the simulation environment of the first wireless scene; and the target pilot pattern is the optimal pilot pattern for the first wireless scene.

After determining the target pilot pattern, a transmitter (Tx) and a receiver (Rx) are aware of the target pilot pattern, and then acquire the partial CSI under the first wireless scene, namely the first CSI, according to the target pilot pattern.

Specifically, the first wireless scene is any first wireless communication scene. The first wireless scene includes information such as a scene size, positions of scatterers within the first wireless scene, sizes of the scatterers, positions of the transmitters, and positions of the receivers.

In the step 201, the multi-view image data of the first wireless scene can be understood as the multi-view image data of the receivers in the first wireless scene. The multi-view image data includes full-view image data. For example, the full-view image data includes image data from the east, west, south, and north directions of the receiver. Therefore, the multi-view image data includes image data from at least one of the east, west, south, and north directions. In other words, the multi-view image data can also be understood as image data from different directions.

Step 202: complete CSI under the first wireless scene is predicted according to the first CSI, the multi-view image data of the first wireless scene and a target channel prediction model.

The target channel prediction model includes: an image feature extraction neural network, the target pilot pattern and a CSI reconstruction neural network. The image feature extraction neural network is configured to extract image features from the multi-view image data of the first wireless scene. The CSI reconstruction neural network is configured to predict the complete CSI according to the image features and the first CSI. The image feature extraction neural network and the CSI reconstruction neural network are obtained by training according to the second CSI being the complete CSI in the simulation environment of the first wireless scene, and the multi-view image data in the simulation environment of the first wireless scene.

Specifically, in the step 202, the image feature extraction neural network is used to extract the image features of the multi-view image data. The CSI reconstruction neural network is used to predict the complete CSI under the first wireless scene according to the image features and the first CSI.

In the step 202, the image feature extraction neural network of the target channel prediction model is used to extract the image features (also referred to as environmental features) in the first wireless scene. The image features are obtained by constructing the relationship between the environment and the channel.

In the step 202, the environmental features of the multi-view image data are extracted through the image feature extraction neural network, and the first CSI, the environmental features and the CSI reconstruction neural network are used to predict the complete CSI (also referred to as overall CSI). In the embodiment of the disclosure, environmental information is introduced in predicting, the introduction of environmental information in the prediction process significantly enhances the accuracy of the overall CSI prediction and reduces the pilot overhead.

Moreover, the channel prediction method is more suitable for diverse and extensive application scenes required by future mobile communication systems and possesses greater scene universality.

In an embodiment, the channel prediction method further includes: obtaining the second CSI from receivers at target positions in the simulation environment of the first wireless scene, and obtaining the multi-view image data from the receivers at the target positions in the simulation environment of the first wireless scene. The target positions include a first position and a second position.

A receiver corresponds to a target position, or it can be understood that a position of the receiver in the first wireless scene is the target position.

Specifically, in the step, in response to the first wireless scene, channel parameters corresponding to each receiver at the target positions are the second CSI. In response to the first wireless scene, red-green-blue (RGB) images in the east, west, south, and north directions of each receiver at the target positions are the multi-view image data of the target position.

The CSI and multi-view image data are aligned according to the target positions to obtain a channel-multi-view image dataset. The channel-multi-view image dataset includes the second CSI and the multi-view image data corresponding to each target position. The target positions include the first position and the second position, that is, the channel-multi-view image dataset includes the second CSI and the multi-view image data corresponding to the first position, and the second CSI and the multi-view image data corresponding to the second position. It should also be noted that the target positions may also include a third position, that is, the channel-multi-view image dataset may also include the second CSI and the multi-view image data corresponding to the third position.

The channel-multi-view image dataset provides the data basis for the subsequent training of the target channel prediction model.

In an embodiment, the second CSI and the multi-view image data corresponding to the first position can be used as a training dataset, the second CSI and the multi-view image data corresponding to the second position can be used as a validation dataset, and the second CSI and the multi-view image data corresponding to the third position can be used as a test dataset, used to train, validate, and test the target channel prediction model, respectively. The proportions of the first position, the second position, and the third position in the target positions can be 0.7:0.1:0.2, respectively.

In an embodiment, a constructing process of the simulation environment includes the following steps.

Environmental information of the first wireless scene is obtained. Specifically, the three-dimensional wireless propagation environment of the first wireless scene is collected, the environmental information of the three-dimensional wireless propagation environment is automatically collected through actual measurement, map-assisted acquisition, and the use of computer vision techniques. The environmental information includes the overall layout of the wireless scene, scatterer information, transmitter and receiver information, such as scene size information, scatterer positions within the scene, scatterer size information, transmitter positions and receiver positions.

The simulation environment of the first wireless scene is constructed by using a modeling tool based on the environmental information. Specifically, the three-dimensional modeling tool, such as Blender software and Google SketchUp software, is used to build a dataset of the wireless propagation environment with scatterer distributions within a coordinate system of the same size as the actual scene, according to the environmental information. The dataset of the wireless propagation environment is the simulation environment of the first wireless scene.

In an embodiment, the obtaining the second CSI from receivers at target positions in the simulation environment of the first wireless scene includes: generating, by using a ray-tracing (RT) channel simulation tool, the second CSI from the receivers at the target positions in the simulation environment of the first wireless scene.

The ray-tracing channel simulation tool is used to generate the second CSI from the receivers at the target positions in the simulation environment of the first wireless scene. Specifically, the ray-tracing channel simulation tool, such as Wireless Insite® software, is used to generate channel parameters corresponding to the position of each receiver, i.e., generate the second CSI at the target positions.

In an embodiment, the obtaining the multi-view image data from the receivers at the target positions in the simulation environment of the first wireless scene includes: obtaining, by using an autonomous driving simulation platform, the multi-view image data from the receivers at the target positions in the simulation environment of the first wireless scene. Specifically, the autonomous driving simulation platform, such as CARLA simulator, is used to collect the RGB images in the east, west, south, and north directions of each receiver at the target position.

A constructing process of the channel-multi-view image dataset is illustrated below through a specific embodiment.

A large outdoor urban scene with a length of 200 meters (m) and a width of 200 m is constructed in RoadRunner (an interactive editor), and a base station is set up to cover the scene. The scene includes four building clusters and four roads, with different types of vehicles randomly placed on the sides of the roads to ensure sufficient diversity in the scenes of different roads. The building clusters, the roads, and the vehicles can all be considered as the scatterers.

The scene is imported into the CARLA simulator, and multi-view image data for different receiver positions is obtained by deploying cameras along the roads at intervals of 0.26 m and capturing multi-view images sequentially.

Since the lack of surface details has a limited impact on channel data, the entire scene is imported into the Blender software for simplification, where the buildings and the vehicles are replaced with simple cuboids. The simplified scene model is then imported into the Wireless InSite® software for ray-tracing simulation to generate channels for different receiver positions and extract CSI data. The number of transmit antennas for the simulated CSI data is Mₜ=128, the number of receive antennas is Nᵣ=1, the number of subcarriers is Nₑ=69, and the number of orthogonal frequency division multiplexing (OFDM) symbols in the time domain is N_{T}=3. The detailed ray-tracing simulation data are shown in Table 1 below.

TABLE 1

| Center frequency | 6775 | MHz |
|---|---|---|
| Bandwidth | 100 | MHz |
| Subcarrier spacing | 120 | kHz |
| Proportion of subcarriers | 1/12 | |
| carrying pilots | | |
| Number of OFDM symbols | 3 | |
| Number of Tx antennas | 128 | |
| Reflection order | 6 | |
| Diffraction order | 1 | |
| Transmit power | 0 | dBm |
| Receive power threshold | −250 | dBm |

| | |
|---|---|
| Number of paths retained per Rx | 5 |
| RT simulation propagation model | X3D |
| Transmit antenna | Isotropic, vertically polarized |
| Receive antenna | Isotropic, vertically polarized |
| Tx location | Located at the center, 1 m above the |
| | rooftop height: 19 m |
| Rx location | Height: 2 m, spacing: 0.26 m |
| | traversing streets |

A training process of the target channel prediction model is provided below.

According to first network hyperparameters of a first neural network, the second CSI at the first position and the multi-view image data at the first position, first image feature extraction parameters of the first neural network, a first pilot pattern, and first CSI reconstruction parameters of a second neural network are trained to obtain second image feature extraction parameters, a second pilot pattern, and second CSI reconstruction parameters.

The first network hyperparameters are initial network hyperparameters which are randomly generated, the first image feature extraction parameters are initial image feature extraction parameters which are randomly generated, and the first CSI reconstruction parameters are randomly-generated CSI reconstruction parameters.

The first neural network can be understood as the image feature extraction neural network before training and optimization. The CSI reconstruction neural network includes the second neural network before optimization training. The type of the first neural network should be consistent with the type of the image feature extraction neural network, and the type of the CSI reconstruction neural network should be consistent with the type of the second neural network.

The first neural network can be a convolutional neural network (CNN) and a self-attention layer, etc. It can be understood that the image feature extraction neural network is consistent in type with the first neural network, and the image feature extraction neural network is obtained by training the first neural network.

The network hyperparameters are variables that determine the network structure (e.g., the number of hidden units) and variables that determine how the network is trained (e.g., the learning rate). In the context of machine learning, the network hyperparameters are parameters whose values are set before the learning process begins, rather than parameters obtained through training. Typically, the network hyperparameters need to be optimized to select an optimal set of hyperparameters for a learning machine to improve its performance and effectiveness.

The first image feature extraction parameters are mainly related to feature extraction, and include weight parameters and bias parameters, etc.

Target image feature extraction parameters are obtained by training and optimizing the first image feature extraction parameters using the training data, i.e., the target image feature extraction parameters include optimal weight parameters and bias parameters, etc.

The second neural network includes a CNN and a recurrent neural network (RNN), etc.

The CSI reconstruction parameters include parameters related to CSI estimation and design parameters of a reconstruction algorithm, etc.

According to the first network hyperparameters of the first neural network, the second CSI at the first position and the multi-view image data at the first position, the first image feature extraction parameters of the first neural network, the first pilot pattern, and the first CSI reconstruction parameters of the second neural network are trained to obtain the second image feature extraction parameters, the second pilot pattern, and the second CSI reconstruction parameters. Specifically, according to the second CSI at the second position and the second pilot pattern, partial CSI corresponding to the second position is obtained. According to the first neural network, the first network hyperparameters of the first neural network, and the second image feature extraction parameters, image features of the multi-view image data at the second position are extracted. Based on the image features of the multi-view image data at the second position, the partial CSI corresponding to the second position, the second neural network, and the first CSI reconstruction parameters of the second neural network, predicted complete CSI at the second position as third CSI is obtained.

First error information and first similarity information between the second CSI at the second position and the third CSI are obtained. The first error information is normalized mean square error (NMSE) and the first similarity information is cosine similarity.

Whether the first error information and the first similarity information meet a first preset condition is determined. The first preset condition includes: the first error information being less than second error information corresponding to a first channel prediction model, and the first similarity information being greater than second similarity information corresponding to the first channel prediction model.

The first channel prediction model includes at least one of a first sub-channel prediction model, a second sub-channel prediction model and a third sub-channel prediction model.

The first sub-channel prediction model includes a randomly generated second pilot pattern and the CSI reconstruction neural network. That is, the first sub-channel prediction model does not perform pilot pattern optimization and does not include an image feature extraction neural network configured to extract image features from multi-view image data (referred to as random sampling without environment).

The second sub-channel prediction model includes: a randomly generated second pilot pattern, the image feature extraction neural network, and the CSI reconstruction neural network. That is, the second sub-channel prediction model does not perform pilot pattern optimization but includes the image feature extraction neural network configured to extract image features from multi-view image data (referred to as random sampling with environment).

The third sub-channel prediction model includes: the target pilot pattern and the CSI reconstruction neural network. That is, the third sub-channel prediction model performs pilot pattern optimization but does not include the image feature extraction neural network configured to extract image features from multi-view image data (referred to as deep probabilistic subsampling (DPS) without environment).

The target channel prediction model is abbreviated as DPS with environment.

The above models are trained for 200 epochs and use the same mean square error (MSE) loss function.

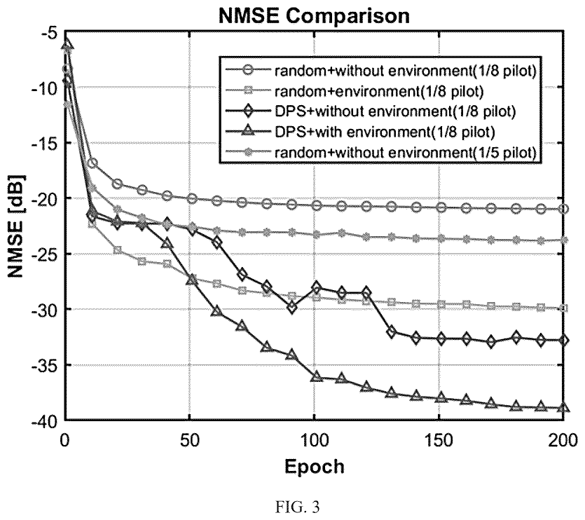

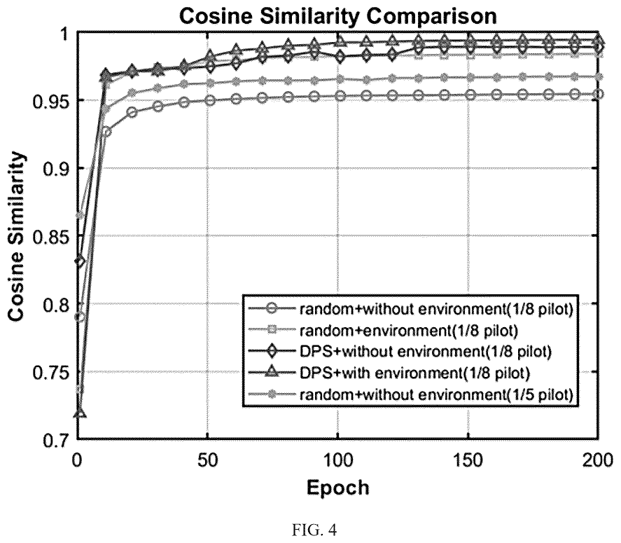

Specifically, the first error information is compared with the second error information corresponding to the first, second, and third sub-channel prediction models, respectively, with comparison results shown in FIG. 3. The first similarity information is compared with the second similarity information corresponding to the first, second, and third sub-channel prediction models, respectively, with comparison results shown in FIG. 4. In FIG. 3 and FIG. 4, “random+without environment” represents “random sampling without environment”, “random+environment” represents “random sampling with environment”, “DPS+without environment” represents “DPS without environment”, and “DPS+with environment” represents “DPS with environment”.

Referring to FIG. 3 and FIG. 4, it may be determined that whether the first error information and the first similarity information meet the first preset condition.

In response to the first error information and the first similarity information not meeting the first preset condition, the first network hyperparameters of the first neural network are adjusted; it is returned to the step that according to first network hyperparameters of a first neural network, the second CSI at the first position and the multi-view image data at the first position, first image feature extraction parameters of the first neural network, a first pilot pattern, and first CSI reconstruction parameters of a second neural network are trained to obtain second image feature extraction parameters, a second pilot pattern, and second CSI reconstruction parameters; it is judged that whether adjusted first error information and adjusted first similarity information meet the first preset condition; when the adjusted first error information and the adjusted first similarity information do not meet the first preset condition, it is continued to return to the step; when the first preset condition is met, the training is ended, the image feature extraction neural network is obtained according to adjusted first network hyperparameters obtained by a final adjustment and the second image feature extraction parameters corresponding to the adjusted first network hyperparameters obtained by the final adjustment, and the second pilot pattern corresponding to the adjusted first network hyperparameters obtained by the final adjustment is taken as the target pilot pattern.

Specifically, after training, the first network hyperparameters of the first neural network are set to the adjusted first network hyperparameters obtained by the final adjustment, the image feature extraction parameters of the first neural network are set to the second image feature extraction parameters corresponding to the adjusted first network hyperparameters obtained by the final adjustment, thereby obtaining the trained image feature extraction neural network. The adjusted first network hyperparameters obtained by the final adjustment are the optimal network hyperparameters, and the second image feature extraction parameters corresponding to the adjusted first network hyperparameters obtained by the final adjustment are the optimal image feature extraction parameters.

As shown in FIG. 3 and FIG. 4, the proposed method (the target channel prediction model) achieves the highest correlation coefficient and the lowest NMSE during the network model training. Comparing the results with and without the pilot optimization module (as shown by a curve with circles and a curve with rectangles, or a curve with rhombus and a curve with triangles), it is apparent that under same environmental conditions, the optimal pilot pattern contributes to enhancing the precision of CSI prediction, with NMSE reductions of approximately 76.4% and 64.7%. Moreover, under the same pilot optimization scheme, the absence of environmental information (as indicated by the curve with circles and the curve with rhombus, or the curve with rectangles and the curve with triangles) reveals that incorporating environmental information yields gains, resulting in NMSE reductions of about 64.2% and 46.4%. Additionally, compared to the ⅕ pilot sampling without environmental information (a curve with star shapes), the CSI prediction performance of the ⅛ pilot with the DPS with environment is superior. The pilot overhead is reduced by at least 37.5%.

Specifically, the overall network of the target neural channel prediction model is composed of three modules including: an image feature extraction module, a pilot optimization module, and a CSI reconstruction neural network.

The step that according to first network hyperparameters of a first neural network, the second CSI at the first position and the multi-view image data at the first position, first image feature extraction parameters of the first neural network, a first pilot pattern, and first CSI reconstruction parameters of a second neural network are trained to obtain second image feature extraction parameters, a second pilot pattern, and second CSI reconstruction parameters includes the following steps.

According to the first image feature extraction parameters of the first neural network, feature extraction is performed on the multi-view image data at the first position by using the first neural network to obtain an environmental feature map. Specifically, multi-view images are obtained and input into the image feature extraction module. The image feature extraction module includes the image feature extraction neural network, and the image features of the multi-view image data are extracted through the image feature extraction neural network.

In the image feature extraction module, since the CNN can extract hierarchical features from the multi-view image data and perform well in visual tasks, three convolutional layers and a pooling layer of the CNN are used to extract the environmental feature map from the panoramic images, which can reflect the scene environment information around the receivers.

In the pilot optimization module, according to the first pilot pattern and the second CSI, partial CSI at the first position as fourth CSI is obtained. A formula is as follows: Hₚₐᵣₜᵢₐₗ=H_{m,n}A; where Hₚₐᵣₜᵢₐₗ represents the fourth CSI, H_{m,n} represents the second CSI, and A represents the first pilot pattern.

According to the first CSI reconstruction parameters of the second neural network, the environmental feature map and the fourth CSI, predicted complete CSI in the simulation environment of the first wireless scene as fifth CSI is obtained.

Loss information between the fifth CSI and the second CSI in the simulation environment of the first wireless scene is obtained.

The first image feature extraction parameters of the first neural network are adjusted according to the loss information, the first pilot pattern is adjusted according to the loss information and a deep probabilistic subsampling algorithm, the first CSI reconstruction parameters of the second neural network are adjusted according to the loss information, and it is returned to the step that according to the first image feature extraction parameters of the first neural network, feature extraction is performed on the multi-view image data at the first position by using the first neural network to obtain an environmental feature map, until a number of iterations reaches a preset number.

Adjusted first image feature extraction parameters obtained by a last adjustment are taken as the second image feature extraction parameters, adjusted first pilot pattern obtained by the last adjustment is taken as the second pilot pattern, and adjusted first CSI reconstruction parameters obtained by the last adjustment are taken as the second CSI reconstruction parameters.

Specifically, the design of low-overhead optimal pilot patterns can be described as a task-adaptive compressive sensing problem, the objective of which is to select the optimal subset of signal samples to achieve end-to-end optimization. For each CSI H_{m,n} (i.e., the second CSI) corresponding to the m-th transmit antenna and the n-th receive antenna, the deep probabilistic subsampling algorithm generates an optimized pilot pattern A∈{0,1}^{N}^{_{T}}^{×N}^{_{c}} (i.e., the adjusted first pilot pattern) in the time-frequency domain based on the loss information. Hₚₐᵣₜᵢₐₗ∈ [symbol] is the CSI (partial CSI) in the time-frequency domain under a given pilot pattern, which can be represented as Hₚₐᵣₜᵢₐₗ=H_{m,n}A. The optimized sampling matrix A has the number of elements with 1 equal to the number of pilots Nₚ. The optimal pilot positions are obtained during the training process of the forward propagation of the neural network. The pilot optimization module enhances the accuracy of channel prediction while minimizing pilot overhead to the greatest extent possible. The pilot sampling ratio is set to ⅛, meaning that ⅛ (N_{c}×N_{T}/8=26) of the elements in A are 1, and the rest are 0. N_{c} represents the number of subcarriers, and N_{T} represents the number of OFDM symbols. After the preset number of iterations (i.e., the preset number), the final optimized pilot pattern is determined as the target pilot pattern. The preset number of iterations is 200 times.

In the CSI reconstruction neural network, the environmental feature map and the partial CSI are used as inputs. According to the first CSI reconstruction parameters, the prediction value of the complete CSI, i.e., the fifth CSI, is obtained.

The loss information between the fifth CSI and the second CSI is obtained through preset loss function.

After each acquisition of the loss information, the first image feature extraction parameters, the first pilot pattern, and the first CSI reconstruction parameters are individually adjusted based on the loss information. Subsequently, it is proceeded to the next iteration until the number of iterations exceeds 200 times, at which point the iteration process is terminated.

In an embodiment, the step that according to the first CSI reconstruction parameters of the second neural network, the environmental feature map and the fourth CSI, predicted complete CSI in the simulation environment of the first wireless scene as fifth CSI is obtained includes the following steps.

The fifth CSI is predicted by using the second neural network and a proximal gradient iteration algorithm according to the first CSI reconstruction parameters of the second neural network, the environmental feature map and the fourth CSI.

Specifically, in the CSI reconstruction neural network, the environmental feature map and the fourth CSI are used as inputs, and the second neural network (including the first CSI reconstruction parameters) is used in conjunction with the proximal gradient iteration algorithm to predict complete channel matrix {H} (i.e., the fifth CSI), thereby accelerating the convergence of the model. The iteration steps are represented as follows:

$$\begin{matrix}{S}^{k + 1} := \{ \begin{matrix}{α}^{0} {H}_{partial} ( k = 0 ) ; \\ {X}^{k} + {α}^{k} ( {H}_{partial} - {X}^{k} * A ) ( k > 0 )\end{matrix} \\ {X}^{k + 1} := {prox}_{k} ( {S}^{k + 1} )\end{matrix}$$

where X^{k} represents a forward value of a k-th iteration, proxₖ represents a proximal gradient operator of the k-th iteration, α^{k} represents a channel prediction parameter of the k-th iteration, X^{k+1} represents a backward value of a k+1-th iteration, and S^{k+1} represents an intermediate variable of the k+1-th iteration. The second neural network is used to perform the proximal gradient operator proxₖ and the channel prediction parameter α^{k}. The algorithm iteration number is set to 2 (i.e., k is equal to 0, 1, 2), the CSI data obtained after iteration is combined with the channel number and image feature mapping, and the complete CSI prediction value (i.e., the fifth CSI) is obtained through the second neural network.

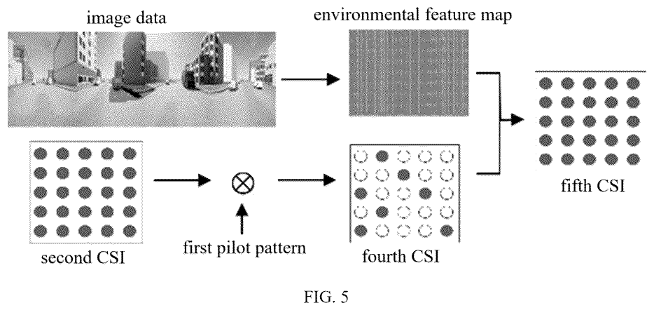

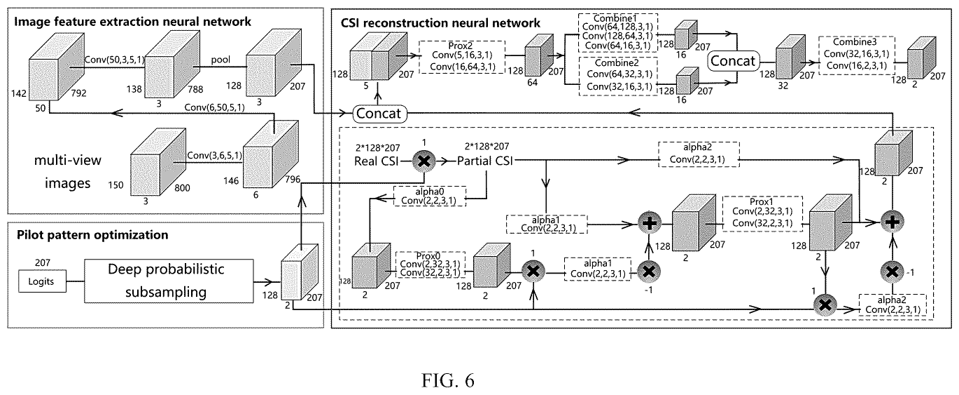

A process of obtaining the fifth CSI is shown in FIG. 5. A schematic structural diagram of neural networks of the target channel prediction model is shown in FIG. 6, where real CSI in FIG. 6 is the second CSI, partial CSI in FIG. 6 is the fourth CSI.

In an embodiment, the channel prediction method further includes the following steps.

Partial CSI at the third position as sixth CSI is obtained according to the second SCI at the third position and the target pilot pattern.

Image features of the multi-view image data at the third position are extracted by using the image feature extraction neural network.

Complete CSI at the third position as seventh CSI is predicted through the CSI reconstruction neural network, according to the image features of the multi-view image data at the third position, and the sixth CSI.

An accuracy of the target channel prediction model is obtained according to third error information and third similarity information between the seventh CSI and the second CSI at the third position.

In the embodiment of the disclosure, the accuracy of the target channel prediction model is tested through the test dataset. The third error information is NMSE, and the third similarity information is cosine similarity information.

By using the test dataset, according to the process of obtaining the fourth CSI, the sixth CSI is obtained, and according to the process of obtaining the fifth CSI, the seventh CSI is obtained. The specific process is not repeated here.

In an embodiment, the channel prediction method further includes the following steps.

Complete CSI in a simulation environment of a second wireless scene as eighth CSI is obtained, and multi-view image data from receivers in the simulation environment of the second wireless scene is obtained.

The second wireless scene can be understood as a new scene different from the first wireless scene. For example, by modifying the layout of buildings and vehicles in the original scene to create a new scene. The dataset (simulation environment) of the new scene contains 1601 receivers at two middle roads.

According to the eighth CSI and the target pilot pattern, partial CSI in the simulation environment of the second wireless scene as ninth CSI is obtained.

Image features of the multi-view image data in the simulation environment of the second wireless scene are extracted by using the image feature extraction neural network.

Predicted complete CSI in the simulation environment of the second wireless scene as tenth CSI is obtained through the CSI reconstruction neural network according to the image features of the multi-view image data in the simulation environment of the second wireless scene and the ninth CSI.

A generalization applicability result of the target channel prediction model is obtained according to fourth error information and fourth similarity information between the tenth CSI and the eighth CSI.

The ninth CSI is obtained through the process of obtaining the fourth CSI, and the tenth CSI is obtained through the process of obtaining the fifth CSI. The specific process is not repeated here.

The fourth error information is NMSE, and the fourth similarity information is cosine similarity information.

In general, the cosine similarity and the NMSE in the new scene are similar to those in the original scene (the first wireless scene), indicating that the target channel prediction model generalizes well.

Furthermore, the cosine similarity and the NMSE in the original scene and the cosine similarity and the NMSE in the new scene under the target channel prediction model, the first sub-channel prediction model, the second sub-channel prediction model, and the third sub-channel prediction model can be compared to obtain the target channel prediction model. The comparison and results are shown in Table 2 below.

TABLE 2

| | |
|---|---|
| Cosine similarity | NMSE |

| | Original | New | Original | New |
|---|---|---|---|---|
| | scene | scene | scene | scene |
| Random sampling | 0.9545 | 0.9478 | 0.0893 | 0.1030 |
| without environment | | | | |
| random sampling | 0.9841 | 0.9796 | 0.0320 | 0.0414 |
| with environment | | | | |
| DPS without | 0.9899 | 0.9840 | 0.0211 | 0.0328 |
| environment | | | | |
| DPS with | 0.9945 | 0.9917 | 0.0113 | 0.0171 |
| environment | | | | |

In summary, the disclosure not only utilizes the powerful feature extraction and non-linear mapping capabilities of AI but also incorporates the environmental feature information provided by images. The accuracy of CSI prediction can be improved while saving pilot overhead, solving the problem of high overhead of CSI acquisition in large-scale MIMO systems, thereby optimize the pilot arrangement scheme. Compared with the random pilot scheme, the disclosure can increase the prediction accuracy, perform efficient and accurate CSI prediction for specific practical application scenes. By introducing environmental information into the CSI prediction process, the adaptability of the AI model to the environment is enhanced. The disclosure is more suitable for the need of the future mobile communication system for a wide variety of application scenes and has better scene universality.

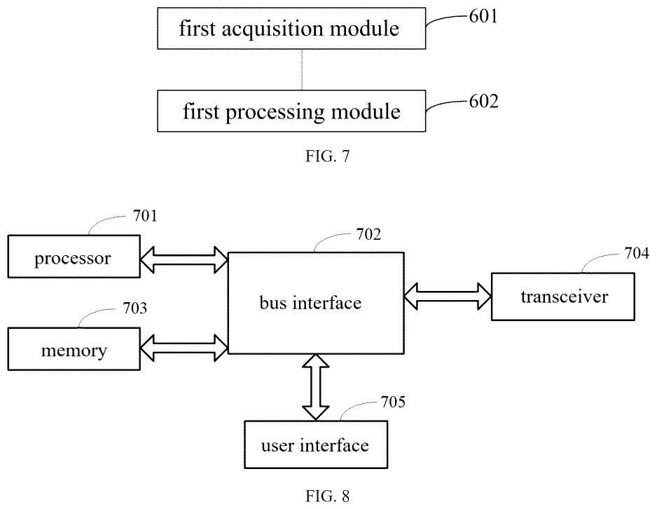

As shown in FIG. 7, the embodiment of the disclosure further provides a channel prediction apparatus, including a first acquisition module 601 and a first processing module 602.

The first acquisition module 601 is configured to acquire partial CSI under a first wireless scene as first CSI according to a target pilot pattern and acquire multi-view image data of the first wireless scene.

The first processing module 602 is configured to predict complete CSI under the first wireless scene according to the first CSI, the multi-view image data of the first wireless scene and a target channel prediction model.

The target channel prediction model includes: an image feature extraction neural network, the target pilot pattern and a CSI reconstruction neural network. The image feature extraction neural network is configured to extract image features from the multi-view image data of the first wireless scene. The CSI reconstruction neural network is configured to predict the complete CSI according to the image features and the first CSI. The image feature extraction neural network, the target pilot pattern and the CSI reconstruction neural network are obtained by training according to second CSI being complete CSI in a simulation environment of the first wireless scene, and multi-view image data in the simulation environment of the first wireless scene.

In an embodiment, the channel prediction apparatus further includes a second acquisition module, a second processing module, a third processing module, a third acquisition module, a fourth processing module and a fifth processing module.

The second acquisition module is configured to acquire the second CSI from receivers at target positions in the simulation environment of the first wireless scene, and acquire the multi-view image data from the receivers at the target positions in the simulation environment of the first wireless scene, where the target positions include a first position and a second position.

The second processing module is configured to train, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters.

The third processing module is configured to predict third CSI at the second position according to the second CSI at the second position, the second pilot pattern, the second image feature extraction parameters, the first network hyperparameters of the first neural network, the multi-view image data at the second position and the second CSI reconstruction parameters.

The third acquisition module is configured to obtain first error information and first similarity information between the second CSI at the second position and the third CSI at the second position.

The fourth processing module is configured to adjust, in response to the first error information and the first similarity information not meeting a first preset condition, the first network hyperparameters of the first neural network.

The fifth processing module is configured to return to the step that train, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters, until the first error information and the first similarity information meet the first preset condition; obtain the image feature extraction neural network according to adjusted first network hyperparameters obtained by a final adjustment and the second image feature extraction parameters corresponding to the adjusted first network hyperparameters obtained by the final adjustment; take the second pilot pattern corresponding to the adjusted first network hyperparameters obtained by the final adjustment as the target pilot pattern; and obtain the CSI reconstruction neural network according to the first CSI reconstruction parameters of the second neural network corresponding to the adjusted first network hyperparameters obtained by the final adjustment.

In an embodiment, the second processing module includes a first processing unit, a second processing unit, a third processing unit, a first acquisition unit, a fourth processing unit, and a fifth processing unit.

The first processing unit is configured to perform, according to the first image feature extraction parameters of the first neural network, feature extraction on the multi-view image data at the first position by using the first neural network to obtain an environmental feature map.

The second processing unit is configured to obtain, according to the first pilot pattern and the second CSI at the first position, partial CSI at the first position as fourth CSI.

The third processing unit is configured to obtain, according to the first CSI reconstruction parameters of the second neural network, the environmental feature map and the fourth CSI, predicted complete CSI in the simulation environment of the first wireless scene as fifth CSI.

The first acquisition unit is configured to obtain loss information between the fifth CSI and the second CSI in the simulation environment of the first wireless scene.

The fourth processing unit is configured to adjust the first image feature extraction parameters of the first neural network according to the loss information, adjust the first pilot pattern according to the loss information and a deep probabilistic subsampling algorithm, adjust the first CSI reconstruction parameters of the second neural network according to the loss information, and return to the step that perform, according to the first image feature extraction parameters of the first neural network, feature extraction on the multi-view image data at the first position by using the first neural network to obtain an environmental feature map, until a number of iterations reaches a preset number.

The fifth processing unit is configured to take adjusted first image feature extraction parameters obtained by a last adjustment as the second image feature extraction parameters, take adjusted first pilot pattern obtained by the last adjustment as the second pilot pattern, and take adjusted first CSI reconstruction parameters obtained by the last adjustment as the second CSI reconstruction parameters.

In an embodiment, the third processing unit is specifically configured to predict the fifth CSI by using the second neural network and a proximal gradient iteration algorithm according to the first CSI reconstruction parameters of the second neural network, the environmental feature map and the fourth CSI.

In an embodiment, the first present condition includes: the first error information being less than second error information corresponding to a first channel prediction model, and the first similarity information being greater than second similarity information corresponding to the first channel prediction model.

The first channel prediction model includes at least one of the following: a first sub-channel prediction model, a second sub-channel prediction model, and a third sub-channel prediction model.

The first sub-channel prediction model includes: a randomly generated second pilot pattern and the CSI reconstruction neural network.

The second sub-channel prediction model includes: a randomly generated second pilot pattern, the image feature extraction neural network, and the CSI reconstruction neural network.

The third sub-channel prediction model includes: the target pilot pattern and the CSI reconstruction neural network.

The channel prediction apparatus further includes: a fourth acquisition module, and a sixth processing module.

The fourth acquisition module is configured to acquire environmental information of the first wireless scene.

The sixth processing module is configured to construct the simulation environment of the first wireless scene by using a modeling tool according to the environmental information of the first wireless scene.

In an embodiment, the second acquisition module further includes a second acquisition unit.

The second acquisition unit is configured to generate, by using a ray-tracing channel simulation tool, the second CSI from the receivers at the target positions in the simulation environment of the first wireless scene.

In an embodiment, the second acquisition module further includes a third acquisition unit.

The third acquisition unit is configured to obtain, by using an autonomous driving simulation platform, the multi-view image data from the receivers at the target positions in the simulation environment of the first wireless scene.

In an embodiment, the target positions further include a third position; and the channel prediction apparatus further includes: a seventh processing module, an eighth processing module, a ninth processing module and a tenth processing module.

The seventh processing module is configured to obtain partial CSI at the third position as sixth CSI according to the second SCI at the third position and the target pilot pattern.

The eighth processing module is configured to extract, by using the image feature extraction neural network, image features of the multi-view image data at the third position.

The ninth processing module is configured to predict, through the CSI reconstruction neural network, complete CSI at the third position as seventh CSI, according to the image features of the multi-view image data at the third position, and the sixth CSI.

The tenth processing module is configured to obtain an accuracy of the target channel prediction model according to third error information and third similarity information between the seventh CSI and the second CSI at the third position.

In an embodiment, the channel prediction apparatus further includes: a fifth acquisition module, an eleventh processing module, a twelfth processing module, a thirteenth processing module, and a fourteenth processing module.

The fifth acquisition module is configured to obtain complete CSI in a simulation environment of a second wireless scene as eighth CSI, and obtain multi-view image data from receivers in the simulation environment of the second wireless scene.

The eleventh processing module is configured to obtain, according to the eighth CSI and the target pilot pattern, partial CSI in the simulation environment of the second wireless scene as ninth CSI.

The twelfth processing module is configured to extract, by using the image feature extraction neural network, image features of the multi-view image data in the simulation environment of the second wireless scene.

The thirteenth processing module is configured to obtain, through the CSI reconstruction neural network, predicted complete CSI in the simulation environment of the second wireless scene as tenth CSI according to the image features of the multi-view image data in the simulation environment of the second wireless scene and the ninth CSI.

The fourteenth processing module is configured to obtain a generalization applicability result of the target channel prediction model according to fourth error information and fourth similarity information between the tenth CSI and the eighth CSI.

It should be noted that the channel prediction apparatus provided in the embodiments of the disclosure is capable of implementing the channel prediction method. Therefore, all embodiments of the channel prediction method are applicable to the channel prediction apparatus and can achieve the same or similar technical effects.

As shown in FIG. 8, the embodiment of the disclosure further provides a channel prediction device, including: a processor 701, and a memory 703 connected to the processor 701 through a bus interface 702. The memory 703 is configured to store a program or instructions used by the processor 701 during operation. The processor 701 is configured to invoke and execute the program and data stored in the memory 703.

A transceiver 704 is connected to the bus interface 702, and configured to receive and transmit data under the control of the processor 701. Specifically, the processor 701 is used to read the program from the memory 703 and execute the following process:
acquiring, according to a target pilot pattern, partial channel state information (CSI) under a first wireless scene as first CSI, and acquiring multi-view image data of the first wireless scene; and
predicting complete CSI under the first wireless scene according to the first CSI, the multi-view image data of the first wireless scene and a target channel prediction model.

The target channel prediction model includes: an image feature extraction neural network, the target pilot pattern and a CSI reconstruction neural network. The image feature extraction neural network is configured to extract image features from the multi-view image data of the first wireless scene. The CSI reconstruction neural network is configured to predict the complete CSI according to the image features and the first CSI. The image feature extraction neural network, the target pilot pattern and the CSI reconstruction neural network are obtained by training according to second CSI being complete CSI in a simulation environment of the first wireless scene, and multi-view image data in the simulation environment of the first wireless scene.

In an embodiment, the process 701 is further configured to execute the following processes:
obtaining the second CSI from receivers at target positions in the simulation environment of the first wireless scene, and obtaining the multi-view image data from the receivers at the target positions in the simulation environment of the first wireless scene, where the target positions include a first position and a second position;
training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters;
predicting third CSI at the second position according to the second CSI at the second position, the second pilot pattern, the second image feature extraction parameters, the first network hyperparameters of the first neural network, the multi-view image data at the second position and the second CSI reconstruction parameters;
obtaining first error information and first similarity information between the second CSI at the second position and the third CSI at the second position;
in response to the first error information and the first similarity information not meeting a first preset condition, adjusting the first network hyperparameters of the first neural network; and
returning to the step of training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters, until the first error information and the first similarity information meet the first preset condition; obtaining the image feature extraction neural network according to adjusted first network hyperparameters obtained by a final adjustment and the second image feature extraction parameters corresponding to the adjusted first network hyperparameters obtained by the final adjustment; taking the second pilot pattern corresponding to the adjusted first network hyperparameters obtained by the final adjustment as the target pilot pattern; and obtaining the CSI reconstruction neural network according to the first CSI reconstruction parameters of the second neural network corresponding to the adjusted first network hyperparameters obtained by the final adjustment.

In an embodiment, the processor 701 is specifically configured to execute the following process:
performing, according to the first image feature extraction parameters of the first neural network, feature extraction on the multi-view image data at the first position by using the first neural network to obtain an environmental feature map;
obtaining, according to the first pilot pattern and the second CSI at the first position, partial CSI at the first position as fourth CSI;
obtaining, according to the first CSI reconstruction parameters of the second neural network, the environmental feature map and the fourth CSI, predicted complete CSI in the simulation environment of the first wireless scene as fifth CSI;
obtaining loss information between the fifth CSI and the second CSI in the simulation environment of the first wireless scene;
adjusting the first image feature extraction parameters of the first neural network according to the loss information, adjusting the first pilot pattern according to the loss information and a deep probabilistic subsampling algorithm, adjusting the first CSI reconstruction parameters of the second neural network according to the loss information, and returning to the step of performing, according to the first image feature extraction parameters of the first neural network, feature extraction on the multi-view image data at the first position by using the first neural network to obtain an environmental feature map, until a number of iterations reaches a preset number; and
taking adjusted first image feature extraction parameters obtained by a last adjustment as the second image feature extraction parameters, taking adjusted first pilot pattern obtained by the last adjustment as the second pilot pattern, and taking adjusted first CSI reconstruction parameters obtained by the last adjustment as the second CSI reconstruction parameters.

In an embodiment, the processor 701 is specifically configured to execute the following process:
predicting the fifth CSI by using the second neural network and a proximal gradient iteration algorithm according to the first CSI reconstruction parameters of the second neural network, the environmental feature map and the fourth CSI.

In an embodiment, the first preset condition includes: the first error information being less than second error information corresponding to a first channel prediction model, and the first similarity information being greater than second similarity information corresponding to the first channel prediction model.

The first channel prediction model includes at least one of the following:
a first sub-channel prediction model, including: a randomly generated second pilot pattern and the CSI reconstruction neural network;
a second sub-channel prediction model, including: a randomly generated second pilot pattern, the image feature extraction neural network, and the CSI reconstruction neural network; and
a third sub-channel prediction model, including: the target pilot pattern and the CSI reconstruction neural network.

In an embodiment, the processor 701 is further configured to execute the following process:
obtaining environmental information of the first wireless scene; and
constructing the simulation environment of the first wireless scene by using a modeling tool according to the environmental information of the first wireless scene.

In an embodiment, the processor 701 is further configured to execute the following process:
generating, by using a ray-tracing channel simulation tool, the second CSI from the receivers at the target positions in the simulation environment of the first wireless scene.

In an embodiment, the processor 701 is further configured to execute the following process:
obtaining, by using an autonomous driving simulation platform, the multi-view image data from the receivers at the target positions in the simulation environment of the first wireless scene.

In an embodiment, the target positions further include a third position.

In an embodiment, the processor 701 is further configured to execute the following process:
obtaining partial CSI at the third position as sixth CSI according to the second SCI at the third position and the target pilot pattern;
extracting, by using the image feature extraction neural network, image features of the multi-view image data at the third position;
predicting, through the CSI reconstruction neural network, complete CSI at the third position as seventh CSI, according to the image features of the multi-view image data at the third position, and the sixth CSI; and
obtaining an accuracy of the target channel prediction model according to third error information and third similarity information between the seventh CSI and the second CSI at the third position.

In an embodiment, the processor 701 is further configured to execute the following process:
obtaining complete CSI in a simulation environment of a second wireless scene as eighth CSI, and obtaining multi-view image data from receivers in the simulation environment of the second wireless scene;
obtaining, according to the eighth CSI and the target pilot pattern, partial CSI in the simulation environment of the second wireless scene as ninth CSI;
extracting, by using the image feature extraction neural network, image features of the multi-view image data in the simulation environment of the second wireless scene;
obtaining, through the CSI reconstruction neural network, predicted complete CSI in the simulation environment of the second wireless scene as tenth CSI according to the image features of the multi-view image data in the simulation environment of the second wireless scene and the ninth CSI; and
obtaining a generalization applicability result of the target channel prediction model according to fourth error information and fourth similarity information between the tenth CSI and the eighth CSI.

In FIG. 8, the bus architecture may include any number of interconnected buses and bridges, specifically linking various circuits represented by one or more processors 701 and memories 703. The bus architecture can also link together a variety of other circuits such as peripheral devices, voltage regulators, and power management circuits, all of which are well-known in the field and thus not further described herein. The bus interface 702 provides a user interface 705. The transceiver 704 can be multiple components, i.e., including a transmitter and a receiver, providing units for communication with various other devices over a transmission medium. The processor 701 is responsible for managing the bus architecture and general processing, and the memory 703 can store data used by the processor 701 during operation.

The embodiment of the disclosure further provides a computer-readable storage medium being a non-transitory computer-readable storage medium, stored with a program or instructions. The program or the instructions are configured to, when executed by a processor, implement the steps of the channel prediction method, and the same technical effect can be achieved. To avoid repetition, it is not repeated here.

In the embodiment of the disclosure, the modules can be implemented in software so as to be executed by various types of processors. For example, an identified executable code module may include one or more physical or logical blocks of computer instructions. For instance, it can be constructed as objects, procedures, or functions. Nevertheless, the executable code of the identified module need not be physically located together but can include different instructions stored in various locations that, when logically combined, form the module and achieve the module's intended purpose.

In practice, an executable code module can be a single instruction or multiple instructions and can even be distributed across multiple code segments, different programs, and across multiple memory devices. Similarly, operational data can be identified within the module and can be implemented and organized in any appropriate form and data structure. The operational data can be collected as a single dataset or distributed in different locations (including on different storage devices), and at least partially can exist only as electronic signals within a system or network.

When modules can be implemented using software, considering the level of existing hardware technology, modules that can be implemented in software, without regard to cost, can also be implemented by those skilled in the art with corresponding hardware circuits. The hardware circuits include conventional very large scale integration (VLSI) circuits or gate arrays and existing semiconductors such as logic chips, transistors, or other discrete components. Modules can also be implemented with programmable hardware devices, such as field programmable gate arrays, programmable array logic, and programmable logic devices, etc.

The above exemplary embodiments are described with reference to the accompanying drawings, and many different forms and embodiments are feasible without departing from the spirit and teachings of the disclosure. Therefore, the disclosure should not be construed as limited to the exemplary embodiments set forth herein. More specifically, these exemplary embodiments are provided to make the disclosure complete and to convey the scope of the disclosure to those skilled in the art. In the figures, the dimensions of components and their relative sizes may be exaggerated for clarity. The terms used herein are for the purpose of describing particular exemplary embodiments and are not intended to be limiting. As used herein, unless the context clearly indicates otherwise, the singular forms “a”, “an”, and “the” are intended to include the plural forms as well. It will be further understood that the terms “comprising” and/or “including” when used in this specification, indicate the presence of the features, integers, steps, operations, components, and/or elements, but are not intended to preclude the presence or addition of one or more other features, integers, steps, operations, components, elements, or groups thereof. Unless otherwise specified, when stating a range of values, the range includes both the minimum and maximum values and any subranges therebetween.

The embodiment of the disclosure further provides a computer program product, including: computer instructions. When the computer instructions are executed by a processer, the processes of the channel prediction method as shown in FIG. 2 are implemented, and the same technical effect can be achieved. To avoid repetition, it is not repeated here.

The above are the illustrated embodiments of the disclosure, and it should be pointed out that for those skilled in the art, several improvements and embellishments can be made without departing from the principles of the disclosure. These improvements and embellishments should also be considered within the scope of protection of the disclosure.

What is claimed is:

1. An environmental communication architecture, comprising:
reconstructing a three-dimensional model of scenes according to environmental multi-modal sensing data obtained by sensing devices comprising: a camera and a radar, wherein the scenes comprise: a first wireless scene and a second wireless scene;
performing wireless knowledge mapping on the three-dimensional model of the scenes according to communication task requirements of a physical layer, a resource layer, a network function layer and an application layer, to extract wireless environmental information related to tasks;
predicting possible channel fading states according to the wireless environmental information and an artificial intelligence (AI) prediction algorithm, wherein the AI prediction algorithm comprises: a first neural network and a second neural network;
generating proactively communication decisions for respective situations according to the possible channel fading states; and
selecting an optimal transmission strategy according to an actual situation.

2. A channel prediction method, comprising:
acquiring, according to a target pilot pattern, partial channel state information (CSI) under a first wireless scene as first CSI, and acquiring multi-view image data of the first wireless scene; and
predicting complete CSI under the first wireless scene according to the first CSI, the multi-view image data of the first wireless scene and a target channel prediction model; and
wherein the target channel prediction model comprises: an image feature extraction neural network, the target pilot pattern and a CSI reconstruction neural network; the image feature extraction neural network is configured to extract image features from the multi-view image data of the first wireless scene; the CSI reconstruction neural network is configured to predict the complete CSI according to the image features and the first CSI; and the image feature extraction neural network, the target pilot pattern and the CSI reconstruction neural network are obtained by training according to second CSI being complete CSI in a simulation environment of the first wireless scene, and multi-view image data in the simulation environment of the first wireless scene.

3. The channel prediction method as claimed in claim 2, further comprising:
obtaining the second CSI from receivers at target positions in the simulation environment of the first wireless scene, and obtaining the multi-view image data from the receivers at the target positions in the simulation environment of the first wireless scene, wherein the target positions comprise a first position and a second position;
training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters;
predicting third CSI at the second position according to the second CSI at the second position, the second pilot pattern, the second image feature extraction parameters, the first network hyperparameters of the first neural network, the multi-view image data at the second position and the second CSI reconstruction parameters;
obtaining first error information and first similarity information between the second CSI at the second position and the third CSI at the second position;
in response to the first error information and the first similarity information not meeting a first preset condition, adjusting the first network hyperparameters of the first neural network; and
returning to the step of training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters, until the first error information and the first similarity information meet the first preset condition;
obtaining the image feature extraction neural network according to adjusted first network hyperparameters obtained by a final adjustment and the second image feature extraction parameters corresponding to the adjusted first network hyperparameters obtained by the final adjustment; taking the second pilot pattern corresponding to the adjusted first network hyperparameters obtained by the final adjustment as the target pilot pattern; and obtaining the CSI reconstruction neural network according to the first CSI reconstruction parameters of the second neural network corresponding to the adjusted first network hyperparameters obtained by the final adjustment.

4. The channel prediction method as claimed in claim 3, wherein the training, according to first network hyperparameters of a first neural network, the second CSI at the first position and the multi-view image data at the first position, first image feature extraction parameters of the first neural network, a first pilot pattern, and first CSI reconstruction parameters of a second neural network to obtain second image feature extraction parameters, a second pilot pattern, and second CSI reconstruction parameters comprises:
performing, according to the first image feature extraction parameters of the first neural network, feature extraction on the multi-view image data at the first position by using the first neural network to obtain an environmental feature map;
obtaining, according to the first pilot pattern and the second CSI at the first position, partial CSI at the first position as fourth CSI;
obtaining, according to the first CSI reconstruction parameters of the second neural network, the environmental feature map and the fourth CSI, predicted complete CSI in the simulation environment of the first wireless scene as fifth CSI;
obtaining loss information between the fifth CSI and the second CSI in the simulation environment of the first wireless scene;
adjusting the first image feature extraction parameters of the first neural network according to the loss information, adjusting the first pilot pattern according to the loss information and a deep probabilistic subsampling algorithm, adjusting the first CSI reconstruction parameters of the second neural network according to the loss information, and returning to the step of performing, according to the first image feature extraction parameters of the first neural network, feature extraction on the multi-view image data at the first position by using the first neural network to obtain an environmental feature map, until a number of iterations reaches a preset number; and
taking adjusted first image feature extraction parameters obtained by a last adjustment as the second image feature extraction parameters, taking adjusted first pilot pattern obtained by the last adjustment as the second pilot pattern, and taking adjusted first CSI reconstruction parameters obtained by the last adjustment as the second CSI reconstruction parameters.

5. The channel prediction method as claimed in claim 4, wherein the obtaining, according to the first CSI reconstruction parameters of the second neural network, the environmental feature map and the fourth CSI, predicted complete CSI in the simulation environment of the first wireless scene as fifth CSI comprises:
predicting the fifth CSI by using the second neural network and a proximal gradient iteration algorithm according to the first CSI reconstruction parameters of the second neural network, the environmental feature map and the fourth CSI.

6. The channel prediction method as claimed in claim 3, wherein the first preset condition comprises:
the first error information being less than second error information corresponding to a first channel prediction model, and the first similarity information being greater than second similarity information corresponding to the first channel prediction model;
wherein the first channel prediction model comprises at least one of the following:
a first sub-channel prediction model, comprising: a randomly generated second pilot pattern and the CSI reconstruction neural network;
a second sub-channel prediction model, comprising: a randomly generated second pilot pattern, the image feature extraction neural network, and the CSI reconstruction neural network; and
a third sub-channel prediction model, comprising: the target pilot pattern and the CSI reconstruction neural network.

7. The channel prediction method as claimed in claim 2, further comprising:
obtaining environmental information of the first wireless scene; and
constructing the simulation environment of the first wireless scene by using a modeling tool according to the environmental information of the first wireless scene.

8. The channel prediction method as claimed in claim 3, wherein the obtaining the second CSI from receivers at target positions in the simulation environment of the first wireless scene comprises:
generating, by using a ray-tracing channel simulation tool, the second CSI from the receivers at the target positions in the simulation environment of the first wireless scene.

9. The channel prediction method as claimed in claim 3, wherein the obtaining the multi-view image data from the receivers at the target positions in the simulation environment of the first wireless scene comprises:
obtaining, by using an autonomous driving simulation platform, the multi-view image data from the receivers at the target positions in the simulation environment of the first wireless scene.

10. The channel prediction method as claimed in claim 3, wherein the target positions further comprise a third position; and the channel prediction method further comprises:
obtaining partial CSI at the third position as sixth CSI according to the second SCI at the third position and the target pilot pattern;
extracting, by using the image feature extraction neural network, image features of the multi-view image data at the third position;
predicting, through the CSI reconstruction neural network, complete CSI at the third position as seventh CSI according to the image features of the multi-view image data at the third position, and the sixth CSI; and
obtaining an accuracy of the target channel prediction model according to third error information and third similarity information between the seventh CSI and the second CSI at the third position.

11. The channel prediction method as claimed in claim 3, further comprising:
obtaining complete CSI in a simulation environment of a second wireless scene as eighth CSI, and obtaining multi-view image data from receivers in the simulation environment of the second wireless scene;
obtaining, according to the eighth CSI and the target pilot pattern, partial CSI in the simulation environment of the second wireless scene as ninth CSI;
extracting, by using the image feature extraction neural network, image features of the multi-view image data in the simulation environment of the second wireless scene;
obtaining, through the CSI reconstruction neural network, predicted complete CSI in the simulation environment of the second wireless scene as tenth CSI according to the image features of the multi-view image data in the simulation environment of the second wireless scene and the ninth CSI; and
obtaining a generalization applicability result of the target channel prediction model according to fourth error information and fourth similarity information between the tenth CSI and the eighth CSI.

12. A channel prediction apparatus, comprising:
a first acquisition module, configured to acquire partial CSI under a first wireless scene as first CSI according to a target pilot pattern and acquire multi-view image data of the first wireless scene; and
a first processing module, configured to predict complete CSI under the first wireless scene according to the first CSI, the multi-view image data of the first wireless scene and a target channel prediction model;
wherein the target channel prediction model comprises: an image feature extraction neural network, the target pilot pattern and a CSI reconstruction neural network; the image feature extraction neural network is configured to extract image features from the multi-view image data of the first wireless scene; the CSI reconstruction neural network is configured to predict the complete CSI according to the image features and the first CSI; and the image feature extraction neural network, the target pilot pattern and the CSI reconstruction neural network are obtained by training according to second CSI being complete CSI in a simulation environment of the first wireless scene, and multi-view image data in the simulation environment of the first wireless scene.

13. A channel prediction device, comprising:
a transceiver, a processor, a memory and a program or instructions stored on the memory and executed on the processor; wherein the program or the instructions are configured to, when are executed by the processor, implement the steps of the channel prediction method as claimed in claim 2.

14. A non-transitory computer-readable storage medium, wherein the non-transitory computer-readable storage medium is stored with a program or instructions, and the program or the instructions are configured to, when are executed by a processor, implement the steps of the channel prediction method as claimed in claim 2.

15. A computer program product, comprising: computer instructions; wherein the computer instructions are configured to, when are executed by a processer, implement the steps of the channel prediction method as claimed in claim 2.
